(19) United States
(12) Patent Application Publication
(10) Pub. No.: US 2026/0079872 A1
(43) Pub. Date: Mar. 19, 2026

(54) SYSTEM WITH A SENSOR SIMULATION COMPUTER AND AN ESI UNIT, AND METHOD FOR OPERATING SUCH A SYSTEM

(71) Applicant: dSPACE GmbH, Paderborn (DE)

(72) Inventors: Gregor SIEVERS, Paderborn (DE); Johannes AX, Paderborn (DE); Henry BATHKE, Paderborn (DE); Aniton ANTONYS, Paderborn (DE)

(73) Assignee: dSPACE GmbH, Paderborn (DE)

(21) Appl. No.: 19/329,999

(22) Filed: Sep. 16, 2025

(30) Foreign Application Priority Data
Sep. 16, 2024 (DE) 10 2024 126 592.2

(51) Int. Cl. G06F 13/42; G06F 13/40; G06F 30/20

(52) U.S. Cl. CPC G06F 13/42; G06F 13/4063; G06F 30/20; G06F 2213/0042

(57) ABSTRACT

A system comprising a sensor simulation computer for calculating model data, an ESI unit for generating raw sensor data and a switching device. The sensor simulation computer has a first DisplayPort connector and a second DisplayPort connector. Two DisplayPort lines are connected to the first DisplayPort connector and four DisplayPort lines are connected to the second DisplayPort connector. The ESI unit has a DisplayPort receiver to which four DisplayPort lines are connected. The switching device is interposed between the first and second DisplayPort connectors and the DisplayPort receiver. The switching device can be configured such that either the two DisplayPort lines connected to the first DisplayPort connector and two DisplayPort lines connected to the second DisplayPort connector are connectable to the four DisplayPort lines connected to the DisplayPort receiver, or the four DisplayPort lines connected to the second DisplayPort connector are connectable to the four DisplayPort lines connected to the DisplayPort receiver.

This nonprovisional application claims priority under 35 U.S. C. § 119(a) to German Patent Application No. 10 2024 126 592.2, which was filed in Germany on Sep. 16, 2024, and which is herein incorporated by reference.

### BACKGROUND OF THE INVENTION

### Field of the Invention

The invention relates to a system comprising a sensor simulation computer for calculating model data based on computer-implemented mathematical models of a vehicle's environment sensors and an ESI unit for generating raw sensor data based on model data obtained from the sensor simulation computer, wherein the sensor simulation computer has a first DisplayPort connector and a second DisplayPort connector, wherein two DisplayPort lines for transmitting DisplayPort data to the ESI unit are connected to the first DisplayPort connector and four DisplayPort lines for transmitting DisplayPort data to the ESI unit are connected to the second DisplayPort connector, and the ESI unit has a DisplayPort receiver to which four DisplayPort lines are connected for receiving DisplayPort data from the sensor simulation computer. The invention also relates to a method for operating such a system.

### Description of the Background Art

Autonomous vehicles represent one of the most significant developments in modern vehicle technology. They have the potential to fundamentally change transportation by increasing safety, optimizing traffic flow, and minimizing human error. A variety of technologies are used to implement these complex systems, of which environmental sensors play a central role. A variety of sensors are used in autonomous vehicles, which use different physical principles to detect the environment of the vehicle. These sensors include radar, lidar, optical cameras and ultrasonic sensors. Each of these sensor types provides specific information about the vehicle's environment and helps to create a comprehensive picture of the environment, which is essential for decision-making in autonomous driving.

Radar sensors work with electromagnetic waves and are particularly useful for measuring distances to objects and determining their speed. They are less susceptible to poor visibility conditions such as fog or darkness, making them an important component in autonomous vehicles. Lidar sensors, on the other side, use laser beams to create precise three-dimensional maps of the environment. This technology provides high-resolution data that makes it possible to accurately detect and locate objects. Cameras provide visual information and are able to distinguish colors and shapes, making them particularly valuable for recognizing traffic signs, traffic lights, and other visual indicators. Ultrasonic sensors complement the system by detecting nearby objects in the vehicle's environment, which is especially beneficial when parking or at low speeds.

To ensure the safety and reliability of autonomous driving functions, it is necessary to comprehensively test and validate these systems. A widely used method for validating the autonomous driving functions is to simulate the sensors at the raw data level. This method simulates the behavior of the various sensors, and often also the behavior of the control units (ECUs) connected to the sensors, in a controlled environment to verify how the vehicle reacts in different situations. Raw data-level simulation aims to generate the data that the sensors would provide in a real-world driving situation. This includes accurately replicating the physical properties of the sensors as well as the environmental conditions in which they operate.

A central aspect of this simulation is the replication of the sensor front end. The sensor front end typically includes the hardware components of a sensor that are responsible for capturing the raw data, such as the camera imager and the lens in a camera system. The first digital interface in the system, which converts the analog signals into digital data, is also simulated. This simulation makes it possible to test the vehicle's reactions to the data provided by the sensors, without the need for physical sensors or real-world test drives. This is especially valuable for testing the vehicle's behavior in extreme or rare conditions that would be difficult to replicate in the real world.

However, simulation at the raw data level places high demands on data processing and the transmission of the simulated sensor data. Since the raw data from sensors such as cameras, lidar or radar can comprise very large amounts of data, efficient and loss-free transmission of this data is crucial. Here, the connection between a sensor simulation computer for calculating model data based on computer-implemented mathematical models of a vehicle's environment sensors and an ESI unit (Environment Sensor Interface) for generating and transmitting raw sensor data based on model data received from the sensor simulation computer come into play. A reliable and fast interface is required to ensure that the simulated sensor data is transmitted to the autonomous vehicle system in real time and without delay. The ESI unit is a hardware unit used to simulate and validate environmental sensors such as cameras, radar and lidar. It enables the time-correlated feeding of raw sensor data into one or more sensor electronic control units (sensor ECUs), which is essential for simulating sensors in a hardware-in-the-loop (HIL) environment for sensor fusion and functional testing.

A sensor simulation computer is a specialized hardware platform designed to generate highly realistic sensor data for the development, testing, and validation of vehicle perception and driving functions. This system runs an advanced software solution that makes it possible to precisely replicate different types of environmental sensors, such as cameras, lidar, radar and ultrasonic sensors, in a virtual environment. The computer is equipped with powerful processors and graphics cards required to handle the complex calculations and detailed visualization of the driving scenarios in real time. By simulating on this computer, developers can integrate the sensor data generated by these virtual sensors into their processes to test and optimize autonomous driving functions and driver assistance systems under a wide range of conditions. The software on the sensor simulation computer makes it possible to create and vary different scenarios, such as different weather conditions, lighting conditions or traffic situations, to ensure that the developed systems work reliably even under extreme or unusual circumstances. In addition, the sensor simulation computer offers a flexible environment in which the integration of the simulated sensor data with existing development and test systems is possible without any problems. This enables seamless validation and optimization of vehicle functions before they need to be verified in real test drives. The ability to generate highly realistic and detailed sensor data in real-time makes this computer a helpful tool for modern vehicle development, especially in areas dealing with autonomous driving and advanced driver assistance systems.

As mentioned above, the term ESI unit (Environment Sensor interface Unit) is used here to describe a hardware unit that is used in particular for the simulation and testing of electrical equipment, such as electric drive systems and wiring systems in vehicles. The ESI unit is designed to support the integration and testing of electrical systems in vehicle development, especially with regard to the simulation of voltage and current curves in real vehicle applications. The ESI unit allows for developers to test electrical systems under realistic conditions without the need for a physical vehicle, in particular in that the ESI unit is able to generate raw sensor data. This is particularly important in the development and validation of electric and hybrid propulsion systems as well as wiring systems, as it makes it possible to simulate and analyze various scenarios and fault states in a safe and controlled manner.

The “DisplayPort” (DP) standard is often chosen as the transmission standard between the sensor simulation computer and the ESI unit. DisplayPort is a widely used standard for transmitting video data and has proven to be suitable for this application due to its high bandwidth and flexibility. DisplayPort makes it possible to transmit large amounts of data quickly and reliably, which is essential for real-time simulation of sensors. The standard also supports the transmission of high-resolution data and multi-channel audio, making it a versatile solution for transmitting sensor data.

A DP receiver, a DP connector, and DP lanes, each with two DP lines, are key components of the DisplayPort standard that work together to enable the transmission of video and audio data from a source, such as a graphics card, to a display device or graphics data processing device, such as a monitor.

The DP receiver is a special chip or circuit in the display device or graphics data processing device whose primary function is to receive and process the digital signals arriving through the DisplayPort connection. This chip decodes the data that is sent over the connection and converts it into a format that the display device or graphics data processing device can use to correctly represent the image and sound. The DP receiver processes not only the visual data, but also additional information such as color data, synchronization signals, and audio content. This processing ensures that the data appears on the screen without delay and in high quality.

The DP connector is the physical connector that creates the connection between the source and the display device or graphics data processing device. This connector ensures that the high-speed signals required for transmitting video and audio data are transmitted safely and reliably. The DP connector provides the necessary electrical contacts through which the data flows from the source to the receiver. It is ruggedly designed to ensure a stable connection and supports functions such as hot plugging, so that the connection can be established or disconnected even during operation without damaging the devices.

The DP lanes are parallel data channels within the DisplayPort connection, each with two DisplayPort lines over which the data is transmitted. Typically, there are four lanes with a total of eight lines working together to provide the bandwidth needed for transmitting high-resolution video and audio. Each lane can transmit data at high speeds, and different numbers of lanes must be used depending on the bandwidth required. The lanes make it possible to transmit large amounts of data efficiently, which is crucial for displaying content in high resolution and with a high refresh rate. They play a key role in transmitting the data in a way that allows for precise and synchronized playback of the content on the display device.

Data transmission over a DisplayPort lane with its two DisplayPort lines is limited by several technical factors resulting from the physical and electrical characteristics of the transmission link as well as the requirements for signal integrity and the complexity of data processing. For example, the bandwidth of a single DisplayPort lane is limited by the physical data rate that can be transmitted securely over the copper lines of the DisplayPort lines. This data rate depends on the clock speed and signal modulation used within the lane. Higher data rates require better materials and more accurate clock controls to ensure signal integrity, which would increase costs and energy consumption. Limiting the data rate per lane is therefore a trade-off between performance, cost and energy efficiency. Signal integrity also plays a crucial role. At very high data rates, signal interference such as noise, attenuation, and electromagnetic interference can increase. These effects degrade the quality of the transmitted signal and can lead to data errors that affect reliable transmission. To maintain signal integrity and avoid errors, the data rate per lane is limited. Another reason for restricting data transmission via a DP lane lies in the structure of the DisplayPort standard itself, which is based on the parallel transmission of data over several lanes. By splitting the total bandwidth across multiple lanes, the standard can achieve a higher total data rate without unduly increasing the signal quality requirements per lane. This allows for more efficient and robust transmission, as potential issues in a single lane do not affect the entire data transmission.

Despite the many advantages that DisplayPort offers as a transmission standard, there are also challenges that must be considered when implementing it in a sensor simulation system. One of the biggest challenges is ensuring the integrity and accuracy of the data being transmitted. In an autonomous vehicle system, the sensor data must be transmitted without loss or distortion, as even the smallest errors in the data could lead to misinterpretations and thus to wrong decisions by the vehicle. DisplayPort was originally developed for the transmission of video data, where a small delay or slight compression may be tolerable. However, in a safety-critical system such as autonomous driving, the highest precision is required. Another problem is the synchronization of the data transmission between the graphics card and the ESI unit. Since the simulated sensor data must be processed in real time, accurate synchronization is crucial to ensure that the data arrives in the right order and at the right time. Any deviation could result in the simulated data not being interpreted correctly, which would affect the validation of the autonomous driving functions. To overcome these challenges, special adjustments and optimizations of the DisplayPort interface are required to meet the high demands of sensor simulation.

### SUMMARY OF THE INVENTION

It is therefore an object of the present invention is to provide a system that can be easily adapted to different requirements.

In an example, a system is provided that comprises a sensor simulation computer for calculating model data on the basis of computer-implemented mathematical models of environment sensors of a vehicle, an ESI unit for generating raw sensor data on the basis of model data obtained from the sensor simulation computer, and a switching device, wherein the sensor simulation computer has a first DisplayPort connector and a second DisplayPort connector, wherein two DisplayPort lines are connected to the first DisplayPort connector for transmitting DisplayPort data to the ESI unit, and four DisplayPort lines for transmitting DisplayPort data to the ESI unit are connected to the second DisplayPort connector, the ESI unit has a DisplayPort receiver to which four DisplayPort lines are connected for receiving DisplayPort data from the sensor simulation computer, the switching device is interposed between the first DisplayPort connector and the second DisplayPort connector on the one side and the DisplayPort receiver on the other, and the switching device is designed, set up and controllable in such a way that either the two DisplayPort lines, which are connected to the first DisplayPort connector and the two DisplayPort lines, which are connected to the second DisplayPort connector are connectable to the four DisplayPort lines, which are connected to the DisplayPort receiver, or the four DisplayPort lines, which are connected to the second DisplayPort connector can be connected to the four DisplayPort lines, which are connected to the DisplayPort receiver.

The invention thus provides a system for the efficient transmission and processing of sensor data. A central component of the system is a sensor simulation computer, which generates realistic model data from a vehicle's environment sensors. This model data is forwarded to an ESI unit, which uses it to simulate raw data that can be processed by the vehicle systems. The system uses two DisplayPort connectors on the sensor simulation computer, each of which provides several DisplayPort lines for transmitting the sensor data to the ESI unit. An essential aspect of the invention is the integrated switching device that is arranged between the DisplayPort connectors and the DisplayPort receiver of the ESI unit. This switching device makes it possible to flexibly control which DisplayPort lines are connected to the DisplayPort receiver. Either two lines from the first DisplayPort connector and two lines from the second connector or all four lines from the second connector can be selected for data transmission, as required.

The advantage of this flexible configuration lies in the optimized data transmission and the adaptability of the system to different requirements. This enables a high data rate and reliability in the transmission of large amounts of sensor data necessary for the real-time simulation of autonomous driving functions. The ability to dynamically control line assignments increases efficiency and reduces the risk of data loss or delays, which is essential for the safe and accurate validation of vehicle systems.

The two DisplayPort lines connected to the first DisplayPort connector and two DisplayPort lines connected to the second DisplayPort connector can be connected to the switching device, and the two DisplayPort lines connected to the second DisplayPort connector and not connected to the switching device can be connected to two DisplayPort lines of the DisplayPort receiver, and there are two DisplayPort lines connected to the switching device on one side and to the two DisplayPort lines of the DisplayPort receiver on the other, which are not already connected to the two DisplayPort lines connected to the second DisplayPort connector, and the switching device is designed, set up and controllable in such a way that the two DisplayPort lines routed from the switching device to the DisplayPort receiver can be connected either to the two DisplayPort lines routed from the first DisplayPort connector to the switching devices or to the DisplayPort lines routed from the second DisplayPort connector to the switching device.

This provides flexibility and efficiency in the transmission of sensor data. By routing two DisplayPort lines from the first DisplayPort connector and two from the second DisplayPort connector into the switching device, the data flows can be dynamically switched between the different lines. At the same time, the other two DisplayPort lines of the second connector are directly connected to the DisplayPort receiver of the ESI unit. This allows for selective control of the data streams, with the switching device designed to route either the data from the two lines of the first DisplayPort connector or that from the two lines of the second connector to the DisplayPort receiver. This allows for the system to prioritize different data streams depending on requirements and application scenarios, ensuring that good and reliable transmission of sensor data is always guaranteed. This flexibility leads to improved utilization of the available bandwidth, as the switching device is able to efficiently manage the data flows, thus ensuring the best possible connection to the sensor electronic control units. This reduces the risk of data transmission errors and enables more precise and faster processing of sensor data, which is especially crucial in safety-critical applications, such as autonomous vehicle control.

Further, the switching device can have a first switching unit and a second switching unit, the two DisplayPort lines connected to the first DisplayPort connector can be connected to the first switching unit, the four DisplayPort lines connected to the second DisplayPort connector can be connected to the second switching unit, two DisplayPort lines can be connected to the first switching unit on the one side and to two DisplayPort lines of the DisplayPort receiver on the other, two DisplayPort lines can be connected to the second switching unit on the one side and to the other two DisplayPort lines of the DisplayPort receiver on the other, two DisplayPort lines can be connected to the first switching unit on the one side and to the second switching unit on the other, and the two switching units are designed, set up and controllable in such a way that two DisplayPort lines connected to the second DisplayPort connector can be connected to the four DisplayPort lines connected to the DisplayPort receiver, either together with the other two DisplayPort lines connected to the second DisplayPort connector or together with the two DisplayPort lines connected to the first DisplayPort connector.

This example of the invention comprises a first and a second switching unit within the switching device. The DisplayPort lines connected to the first DisplayPort connector are connected to the first switching unit, while the lines connected to the second DisplayPort connector are connected to the second switching unit. In addition, two DisplayPort lines are connected to both the first switching unit and the DisplayPort receiver, as well as two other lines connected to the second switching unit and the receiver. A special functionality of this example lies in the connection of two DisplayPort lines of the first switching unit to the second switching unit, which enables seamless switching. This configuration provides the ability to route the two DisplayPort lines connected to the second DisplayPort connector to the DisplayPort receiver either in combination with the other two lines of the second connector or together with the two lines of the first connector. This ensures good adaptability to different data requirements and transmission conditions by allowing a choice between different data paths as needed. The switching units ensure that data transmission is always reliable and with a high level of integrity, as it offers the possibility of always controlling the connections in such a way that stable and interference-free transmission of the sensor data is ensured.

The first switching unit and the second switching unit can each have a USB-C retimer. A retimer in USB-C is a special chip that has the task of improving and restoring signal quality in high-speed connections. USB-C lines and connections, especially longer lines or high-data rate connections such as USB 3.2, USB4, or Thunderbolt 3 and 4, may experience signal degradation due to attenuation, signal distortion, and interference, which can lead to data transmission errors. The retimer performs several important functions to address these issues. It receives the incoming signal, prepares it, removes distortion and amplifies it before it is forwarded. This “regenerates” the signal and it appears like a fresh, clean signal. In addition, the retimer removes jitter, i.e., small, unwanted deviations in the time intervals of a signal, and ensures that the time intervals between the signal pulses are consistent again. Another important aspect is signal re-clocking, in which the retimer re-clocks the signal and then forwards it, which helps to maintain signal integrity, especially over longer distances or at high data transmission rates. Some retimers also perform basic error corrections by resynchronizing data and ensuring that the transmitted information arrives correctly. Retimers are therefore particularly important in scenarios where high data rates are transmitted over longer lines or complex connections, as they ensure that the signal quality remains sufficiently high to ensure reliable and error-free data transmission. Incidentally, such a USB-C retimer also enables the switching functions of the switching units required here.

The ESI unit can have an FPGA and the DisplayPort lines routed to the DisplayPort receiver are connected to the DisplayPort receiver via an FMC connector. An FPGA mezzanine card connector (FMC connector) is an interface unit that is used to connect FPGA modules (field-programmable gate arrays) to other hardware components or systems. The FMC connector enables flexible and powerful expansion of the functionality of FPGA modules by connecting to external peripherals or other electronic systems. An FMC connector is typically used in combination with FPGA boards, which are used in the development and testing of real-time systems and hardware-in-the-loop (HIL) simulations. These connectors provide a standardized connection that supports high data rates and a wide range of signal types, which is important for demanding applications such as the simulation of complex control and regulation systems in the automotive sector. By using FMC connectors, the functionality of such systems can be extended by connecting additional I/O modules, sensors, or other specialized hardware in order to meet specific requirements.

The sensor simulation computer can have a graphics processing unit. A graphics processing unit (GPU) may be an integrated circuit that is designed either as a component of a main processing unit (CPU) or as a stand-alone electronic component distinct from the main processor. The GPU is specially designed to relieve the main processor by taking over calculations of graphics data. It is characterized by its ability to efficiently perform parallelized computing operations, which makes it particularly suitable for processing image and video data, as well as for other computationally intensive tasks that occur in modern graphical applications and algorithms.

The environment sensors simulated by means of the sensor simulation computer can comprise a radar sensor, a lidar sensor and/or a camera sensor.

The invention also relates to the use of a system described above, wherein sensor data is either passed to the first DisplayPort connector and to the second DisplayPort connector, which can each be transmitted via a maximum of two DisplayPort lines due to the maximum bandwidth of a respective DisplayPort line, or sensor data is passed to the second DisplayPort connector, which can be transmitted over a maximum of four DisplayPort lines but requires more than two DisplayPort lines to transmit.

This provides a flexible and reliable solution for transmitting sensor data that must meet different bandwidth requirements. When sensor data is passed to the first and second DisplayPort connectors, each of which can be transmitted over a maximum of two DisplayPort lines due to their bandwidth, the system enables efficient distribution of data streams. This distribution ensures that the data transmission is stable and with high accuracy, which is crucial for the precise processing of the sensor data in real time. On the other side, if sensor data is passed to the second DisplayPort connector that requires higher bandwidth and therefore needs to be transmitted over more than two DisplayPort lines, the system offers the ability to use up to four lines for transmission. This ensures that even larger amounts of data can be transmitted securely and without bottlenecks, which is particularly important in order to maintain the quality and integrity of the sensor data. The system's ability to automatically adapt to bandwidth requirements ensures good and reliable performance, regardless of whether it is smaller or larger amounts of data. This flexibility makes the system a robust solution that meets the high requirements of modern vehicle technologies and at the same time ensures smooth and error-free data transmission.

The invention also relates to a method for operating a system comprising a sensor simulation computer that calculates model data based on computer-implemented mathematical models of a vehicle's environment sensors, and an ESI unit that generates raw sensor data based on model data obtained from the sensor simulation computer, wherein the sensor simulation computer has a first DisplayPort connector and a second DisplayPort connector, with two DisplayPort lines attached to the first DisplayPort connector for transmitting DisplayPort data to the ESI unit and four DisplayPort lines connected to the second DisplayPort connector for transmitting DisplayPort data to the ESI unit, and the ESI unit has a DisplayPort receiver to which our DisplayPort lines are connected for receiving DisplayPort data from the sensor simulation computer, comprising the following method steps:
a) Connect the two DisplayPort lines connected to the first DisplayPort connector as well as two DisplayPort lines connected to the second DisplayPort connector to the four DisplayPort lines connected to the DisplayPort receiver or
b) Connect the DisplayPort lines connected to the second DisplayPort connector to the four DisplayPort lines connected to the DisplayPort receiver.

An example of this method is that the execution of step a) or step b) is selected by a system described above, depending on whether the maximum bandwidth of a given DisplayPort line is above a predefined bandwidth or not.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically shows, a system according to an example of the invention,

FIG. 2 schematically shows, a system according to an example of the invention and

FIG. 3 schematically shows, a system according to an example of the invention.

### DETAILED DESCRIPTION

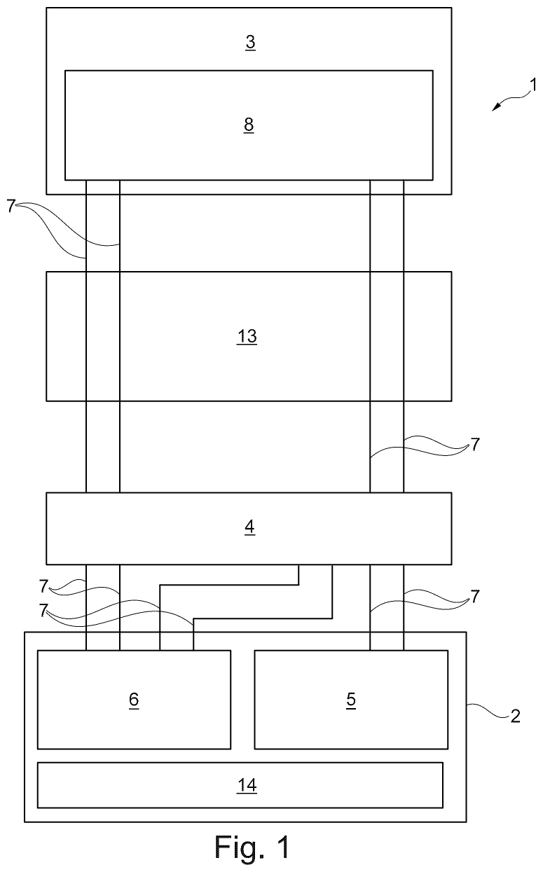

According to an example of the invention, FIG. 1 schematically shows a system 1 with a sensor simulation computer 2 for calculating model data on the basis of computer-implemented mathematical models of environment sensors of a vehicle, an ESI unit 3 for generating raw sensor data on the basis of model data obtained from the sensor simulation computer 2 and a switching device 4. The environment sensors simulated by the sensor simulation computer 2 include, for example, a radar sensor, a lidar sensor and/or a camera sensor.

The sensor simulation computer 2 now has a first DisplayPort connector 5 and a second DisplayPort connector 6, wherein two DisplayPort lines 7 are connected to the first DisplayPort connector 5 for transmitting DisplayPort data to the ESI unit 3 and four DisplayPort lines 7 are connected to the second DisplayPort connector 6 for transmitting DisplayPort data to the ESI unit 3, and the ESI Unit 3 has a DisplayPort receiver 8 to which four DisplayPort lines 7 are connected for receiving DisplayPort data from the sensor simulation computer 2. The switching device 4 is interposed between the first DisplayPort connector 5 and the second DisplayPort connector 6 on the one side and the DisplayPort receiver 8 on the other.

This switching device 4 is designed, set up and controllable in such a way that either the two DisplayPort lines 7 connected to the first DisplayPort connector 5 and two DisplayPort lines 7 connected to the second DisplayPort connector 6 can be connected to the four DisplayPort lines 7 connected to the DisplayPort receiver 8, or the four DisplayPort lines 7 connected to the second DisplayPort connector 6 can be connected to the four DisplayPort lines 7 connected to the DisplayPort receiver 8. The ESI unit 3 is formed by an FPGA and the DisplayPort lines 7 routed to the DisplayPort receiver 8 are connected to the DisplayPort receiver 8 via an FMC connector 13. In addition, the sensor simulation computer 2 is equipped with a Graphics Processing Unit 14.

This provides a flexible configuration that is advantageous in that it provides improved data transmission and good adaptability of the system to different requirements. This enables a high data rate as well as reliability in the transmission of large amounts of sensor data required for the real-time simulation of autonomous driving functions. The ability to dynamically adjust line assignments increases efficiency and minimizes the risk of data loss or delays, which is critical for the safe and accurate validation of vehicle systems.

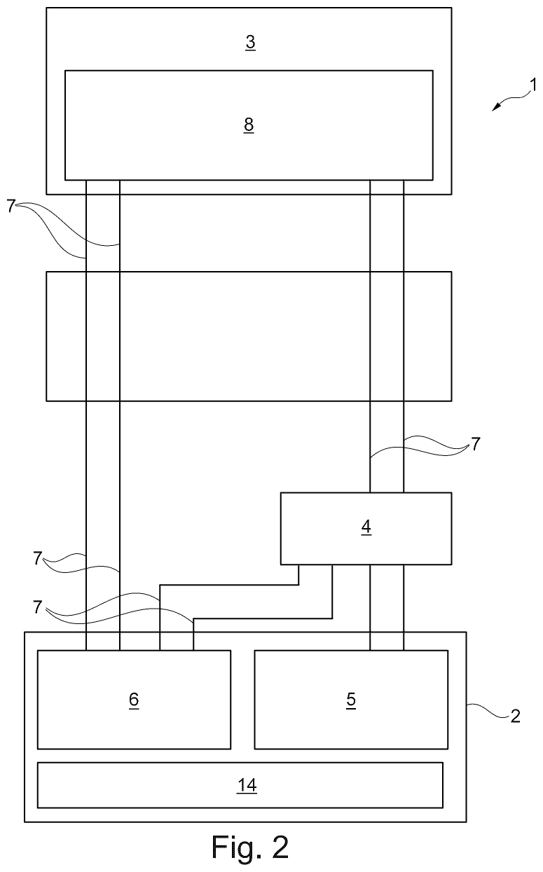

According to an example of the invention schematically illustrated in FIG. 2, a system 1 is provided, wherein the two DisplayPort lines 7 connected to the first DisplayPort connector 5 and two DisplayPort lines 7 connected to the second DisplayPort connector 6 are connected to the switching device 4, the two DisplayPort lines 7 connected to the second DisplayPort connector 6 and not connected to the switching device 4 are connected to two DisplayPort lines 7 of the DisplayPort receiver 8 and two DisplayPort lines 7 are connected to the switching device 4 on the one side and to the two DisplayPort lines 7 of the DisplayPort receiver 8 on the other, which are not already connected to the two DisplayPort lines 7 connected to the second DisplayPort connector 6. The switching device 4 is designed, set up and controllable in such a way that the two DisplayPort lines 7 routed from the switching device 4 to the DisplayPort receiver 8 can be connected either to the two DisplayPort lines 7 routed from the first DisplayPort connector 5 to the switching device 4 or to the DisplayPort lines 7 routed from the second DisplayPort connector 6 to the switching device 4.

By routing two DisplayPort lines 7 from the first DisplayPort connector 5 and two additional DisplayPort lines 7 from the second DisplayPort connector 6 to the switching device 4, the data streams can be dynamically switched between the various DisplayPort lines 7. At the same time, the remaining DisplayPort lines 7 of the DisplayPort connector 6 are directly connected to the DisplayPort receiver 8 of the ESI unit 3. This way, the switching device 4 can forward the data streams from the DisplayPort lines 7 of the first DisplayPort connector 5 or the second DisplayPort connector 6 to the DisplayPort receiver 8. This allows for the system 1 to prioritize different data streams depending on demand and application and to always ensure a good and reliable transmission of the sensor data. This flexibility improves the use of available bandwidth by allowing for the switching device 4 to efficiently control the data streams.

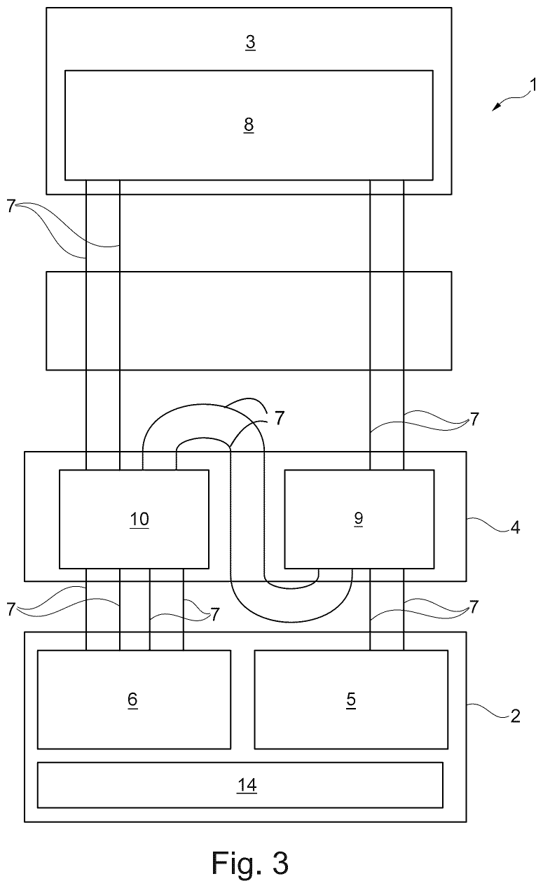

Further, a system 1 is provided according to an example of the invention, as shown schematically in FIG. 3. In this case, the switching device 4 has a first switching unit 9 and a second switching unit 10. Furthermore, the two DisplayPort lines 7 connected to the first DisplayPort connector 5 are connected to the first switching unit 9, the four DisplayPort lines 7 connected to the second DisplayPort connector 6 are connected to the second switching unit 10, two DisplayPort lines 7 are connected to the first switching unit 9 on the one side and two DisplayPort lines 7 of the DisplayPort receiver 8 on the other, two DisplayPort lines 7 are connected to the second switching unit 10 on the one side, and to the other two DisplayPort lines 7 of the DisplayPort receiver 8 on the other, and two DisplayPort lines 7 are connected to the first switching unit 9 on the one side and to the second switching unit 10 on the other. The decisive factor now is that the two switching units 9, 10 are designed, set up and controllable in such a way that two DisplayPort lines 7 connected to the second DisplayPort connector 6 can be connected, either together with the other two DisplayPort lines 7 connected to the second DisplayPort connector 6 or together with the two DisplayPort lines 7 connected to the first DisplayPort connector 5, to the four DisplayPort lines 8 connected to the DisplayPort receiver 8.

This example of the invention thus comprises a first switching unit 9 and a second switching unit 10 within the switching device 4. A special function of this example is the connection between two DisplayPort lines 7 of the first switching unit 9 and the second switching unit 10, which enables seamless switching. This configuration offers the ability to route the two DisplayPort lines 7, which are connected to the second DisplayPort connector 6, either in combination with the other two DisplayPort lines 7 of the second DisplayPort connector 6 or together with the two DisplayPort lines 7 of the first DisplayPort connector 5 to the DisplayPort receiver 8. This ensures good adaptability to different data requirements and transmission conditions by allowing a choice between different data paths as needed. The switching units 9 and 10 ensure that data transmission is always reliable and with high integrity, as they offer the possibility of controlling the connections in such a way that stable and interference-free transmission of the sensor data is ensured.

Incidentally, in the example schematically shown in FIG. 3, the first switching unit 9 and the second switching unit 10 are each formed by a USB-C retimer. The USB-C retimer is often a special electronic chip or a region of an electronic chip that improves and restores signal quality in high-speed connections. With USB-C lines, especially with longer connections or with high data rates such as USB 3.2, USB4, or Thunderbolt, signal degradation can occur due to attenuation, distortion, and interference, which can lead to transmission errors. The retimer receives the signal, prepares it, removes distortion, amplifies it, and forwards it. It regenerates the signal, removes jitter, i.e., unwanted time deviations, and ensures consistent signal intervals. In addition, the retimer re-clocks the signal, which preserves signal integrity over longer distances or at high data rates. Some retimers also perform bug fixes by resynchronizing data. Retimers are particularly important to ensure reliable and error-free transmission at high data rates and with long lines. It is particularly advantageous that such USB-C retimers can also provide the necessary switching functions of the present switching units 9 and 10.

The systems 1 described above can be used in such a way that sensor data is transmitted either to the first DisplayPort connector 5 and to the second DisplayPort connector 6, which can be transmitted via a maximum of two DisplayPort lines 7 due to the maximum bandwidth of a respective DisplayPort line 7, or sensor data is transmitted to the second DisplayPort connector 6, which can be transmitted via a maximum of four DisplayPort lines 7 but requires more than two DisplayPort lines 7 for transmission.

In this respect, a method for operating such a system 1 is provided, which comprises the following method steps:
(a) Connect the two DisplayPort lines 7 connected to the first DisplayPort connector 5 and two DisplayPort lines 7 connected to the second DisplayPort connector 6 to the four DisplayPort lines 7 connected to the DisplayPort receiver 8, or
b) Connect the four DisplayPort lines 7 connected to the second DisplayPort connector 6 to the four DisplayPort lines 7 connected to the DisplayPort receiver 8.

In the present case, the execution of step a) or step b) is selected by a system 1 depending on whether the maximum bandwidth of a respective DisplayPort line 7 is above a predefined bandwidth or not.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A system comprising:
a sensor simulation computer to calculate model data based on computer-implemented mathematical models of environment sensors of a vehicle;
an ESI unit to generate raw sensor data based on the basis of model data obtained from the sensor simulation computer; and
a switching device,
wherein the sensor simulation computer has a first DisplayPort connector and a second DisplayPort connector,
wherein two DisplayPort lines are connected to the first DisplayPort connector to transmit DisplayPort data to the ESI unit and four DisplayPort lines are connected to the second DisplayPort connector to transmit DisplayPort data to the ESI unit,
wherein the ESI unit has a DisplayPort receiver to which four DisplayPort lines are connected to receive DisplayPort data from the sensor simulation computer,
wherein the switching device is interposed between the first DisplayPort connector and the second DisplayPort connector on one side and the DisplayPort receiver on the other side, and
wherein the switching device configured such that either the two DisplayPort lines connected to the first DisplayPort connector and two DisplayPort lines connected to the second DisplayPort connector are connectable to the four DisplayPort lines connected to the DisplayPort receiver, or the four DisplayPort lines connected to the second DisplayPort connector are connectable to the four DisplayPort lines connected to the DisplayPort receiver.

2. The system according to claim 1, wherein the two DisplayPort lines connected to the first DisplayPort connector and the two DisplayPort lines connected to the second DisplayPort connector are connected to the switching device, wherein the two DisplayPort lines connected to the second DisplayPort connector and not connected to the switching device are connected to two DisplayPort lines of the DisplayPort receiver, wherein the two DisplayPort lines are connected to the switching device on the one side and to the two DisplayPort lines of the DisplayPort receiver on the other side, which are not already connected to the two DisplayPort lines connected to the second DisplayPort connector, and wherein the switching device is configured such that the two DisplayPort lines routed from the switching device to the DisplayPort receiver are connectable either to the two DisplayPort lines routed from the first DisplayPort connector to the switching device or to the DisplayPort lines routed from the second DisplayPort connector to the switching device.

3. The system according to claim 1, wherein the switching device comprises a first switching unit and a second switching unit, wherein the two DisplayPort lines connected to the first DisplayPort connector are connected to the first switching unit, wherein the four DisplayPort lines connected to the second DisplayPort connector are connected to the second switching unit, wherein two DisplayPort lines are connected to the first switching unit on the one side and to two DisplayPort lines of the DisplayPort receiver on the other side, wherein two DisplayPort lines are connected to the second switching unit on the one side and to the other two DisplayPort lines of the DisplayPort receiver on the other side, wherein two DisplayPort lines are connected to the first switching unit on the one side and to the second switching unit on the other side, and wherein the two switching units configured such that two DisplayPort lines are connectable to the second DisplayPort connector, either together with the other two DisplayPort lines connected to the second DisplayPort connector or together with the two DisplayPort lines connected to the first DisplayPort connector, to the four DisplayPort lines connected to the DisplayPort receiver.

4. The system according to claim 3, wherein the first switching unit and the second switching unit each have a USB-C retimer.

5. The system according to claim 1, wherein the ESI unit has an FPGA, and wherein the DisplayPort lines routed to the DisplayPort receiver are connected to the DisplayPort receiver via an FMC connector.

6. The system according to claim 1, wherein the sensor simulation computer comprises a Graphics Processing Unit.

7. The system according to claim 1, wherein the environment sensors simulated by the sensor simulation computer comprise a radar sensor, a lidar sensor and/or a camera sensor.

8. The system according to claim 1, wherein sensor data is either passed to the first DisplayPort connector and to the second DisplayPort connector, which is in each case transmittable via a maximum of two DisplayPort lines due to the maximum bandwidth of a respective DisplayPort line, or sensor data is passed to the second DisplayPort connector, which is transmittable via a maximum of four DisplayPort lines but has more than two DisplayPort lines for transmission.

9. A method for operating a system comprising a sensor simulation computer, which calculates model data based on computer-implemented mathematical models of environment sensors of a vehicle, and an ESI unit with which raw sensor data is generated on the basis of model data obtained from the sensor simulation computer, the method comprising:
providing the sensor simulation computer with a first DisplayPort connector and a second DisplayPort connector, wherein two DisplayPort lines are connected to the first DisplayPort connector for transmitting DisplayPort data to the ESI unit and four DisplayPort lines are connected to the second DisplayPort connector for transmitting DisplayPort data to the ESI unit, and wherein the ESI unit has a DisplayPort receiver to which four DisplayPort lines are connected for receiving DisplayPort data from the sensor simulation computer; and
connecting the two DisplayPort lines connected to the first DisplayPort connector and two DisplayPort lines connected to the second DisplayPort connector to the four DisplayPort lines connected to the DisplayPort receiver; or
connecting the four DisplayPort lines connected to the second DisplayPort connector to the four DisplayPort lines connected to the DisplayPort receiver.

10. The method according to claim 9, wherein the execution of the steps of connecting is selected by the system depending on whether or not a maximum bandwidth of a given DisplayPort line is above a predefined bandwidth.
